(19) United States
(12) Patent Application Publication
(10) Pub. No.: US 2026/0114070 A1
(43) Pub. Date: Apr. 23, 2026

(54) METHOD FOR MANUFACTURING SEMICONDUCTOR DEVICE, GRAYSCALE MASK, AND SEMICONDUCTOR DEVICE

(71) Applicant: LITE-ON SINGAPORE PTE. LTD., Singapore (SG)

(72) Inventors: RUI-TAO ZHENG, Singapore (SG); SIN-HENG LIM, SINGAPORE (SG); WUI-PIN LEE, Singapore (SG)

(21) Appl. No.: 19/358,455

(22) Filed: Oct. 15, 2025

(30) Foreign Application Priority Data
Oct. 14, 2025 (CN) 202511464536.3
Oct. 18, 2024 (SG) 10202403245U

(51) Int. Cl. H10F 71/00; G03F 1/38; G03F 7/00; H10F 77/42

(52) U.S. Cl. CPC H10F 71/134; G03F 1/38; G03F 7/70416; H10F 77/488

(57) ABSTRACT

A method for manufacturing a semiconductor device, a grayscale mask, and a semiconductor device. The method includes providing a substrate and forming an inorganic layer and a photoresist layer thereon. A grayscale mask is arranged, which includes a first mask having two light-transmitting regions and a second mask having two light filtering regions with different light transmittances. Exposure light passes through the grayscale mask to perform a single exposure process with different exposure energies on the photoresist layer. After development, a photoresist pattern having a height difference is formed. Finally, the photoresist pattern is transferred onto the inorganic layer by ion etching so that the inorganic layer is formed into an etched microstructure having a corresponding height difference.

This application claims the benefit of priorities to Singapore Provisional Patent Application No. 10202403245U, filed on October 18, 2024, and China Patent Application No. 202511464536.3, filed on October 14, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method for manufacturing a semiconductor device, and more particularly to a method for manufacturing a semiconductor device, a grayscale mask, and a semiconductor device.

### BACKGROUND OF THE DISCLOSURE

The rapid advancement of micro-optical technology, photoelectric sensing components, and microstructure devices has created a growing demand for photolithography processes capable of achieving highly precise structural control. Many emerging components require the formation of multi-level stepped structures to fulfill optical and sensing applications.

Conventional grayscale lithography methods generally employ electron beam (EB) direct writing to fabricate grayscale masks. The EB-based approach enables precise control of grayscale levels; however, the EB process involves high production cost and long fabrication time. Other approaches use multiple mask exposures combined with multi-step etching to form grayscale structures. These approaches inevitably increase process complexity and alignment errors and are difficult to integrate efficiently with wafer structures containing photoelectric sensing elements.

Therefore, the semiconductor industry urgently requires a fabrication method capable of forming multi-level grayscale structures through a simplified and low-cost process within a single photolithography exposure step, while enabling precise integration with wafer-based devices to enhance production efficiency and structural accuracy and to overcome the limitations of the related art.

### SUMMARY OF THE DISCLOSURE

The present disclosure provides a method for manufacturing a semiconductor device, a grayscale mask, and a semiconductor device to solve the above-mentioned problems.

In order to solve the above-mentioned problems, one of the technical aspects adopted by the present disclosure is to provide a method for manufacturing a semiconductor device. The method includes: providing a substrate; forming an inorganic layer on the substrate; forming a photoresist layer on the inorganic layer; performing a photolithography process on the photoresist layer through a grayscale mask to form a photoresist pattern having a height difference; and performing a pattern transfer process to transfer the photoresist pattern to the inorganic layer by ion etching so that the inorganic layer is formed in to an etched microstructure having a height difference. The grayscale mask includes a first mask having a light-shielding region and two light-transmitting regions located on two sides of the light-shielding region, and a second mask optically stacked with the first mask. The second mask has a first light filtering region and a second light filtering region respectively aligned with the two light-transmitting regions along an exposure path, in which the first light filtering region and the second light filtering region have different light transmittances.

In another one of the technical aspects adopted by the present disclosure is to provide a grayscale mask suitable for use in an exposure process of a semiconductor device and a semiconductor device that includes a substrate and an etched microstructure.

Therefore, the method for manufacturing the semiconductor device according to the embodiment of the present disclosure utilizes a grayscale mask having regions of different light transmittances. Through a single exposure process, microstructures with height differences can be formed on the photoresist layer. Subsequently, by performing pattern transfer and etching processes, corresponding etched microstructures with height differences are obtained.

Compared with conventional photolithography processes using electron beam (EB) direct writing or multiple mask exposures, the method of the present disclosure significantly shortens the fabrication steps, reduces manufacturing cost and processing time, and minimizes structural accuracy loss caused by multiple alignment errors. As a result, manufacturing efficiency and yield are remarkably improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 to FIG. 9 are schematic diagrams illustrating steps S101 to S109 of a method for manufacturing a semiconductor device according to an embodiment of the present disclosure; and

FIG. 5B is a schematic diagram illustrating another embodiment of a grayscale mask shown in FIG. 5A.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Method for Manufacturing Semiconductor Device]

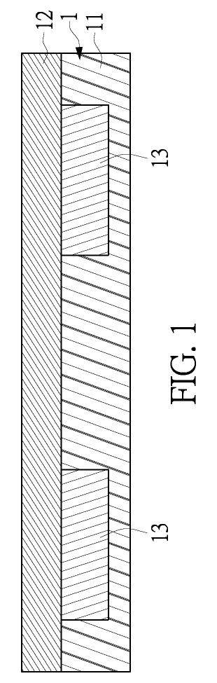

Referring to FIG. 1 to FIG. 9, an embodiment of the present disclosure provides a method for manufacturing a semiconductor device E, and particularly provides to a method for manufacturing a multi-spectral optical filter. The method includes steps S101 to S109.

Step S101 includes providing a substrate 1. As shown in FIG. 1, the substrate 1 includes a base 11 and a film layer 12 formed on the base 11. The base 11 includes a plurality of sensing regions 13 that are spaced apart from each other. Each of the sensing regions 13 can be formed by doping downward from a surface of the base 11 through a semiconductor process. Alternatively, a photo-sensing element, such as a photo detector (PD), can be disposed on the base 11. In the present embodiment, two sensing regions 13 are illustrated as an example, but the present disclosure is not limited thereto. In addition, the film layer 12 covers the two sensing regions 13. The base 11 can be made of silicon dioxide. The film layer 12 can be a reflective layer, for example, formed by stacking multiple layers of silver (Ag) or configured as a distributed Bragg reflector (DBR) to improve transmission efficiency and spectral resolution of the multi-spectral optical filter, but the present disclosure is not limited thereto.

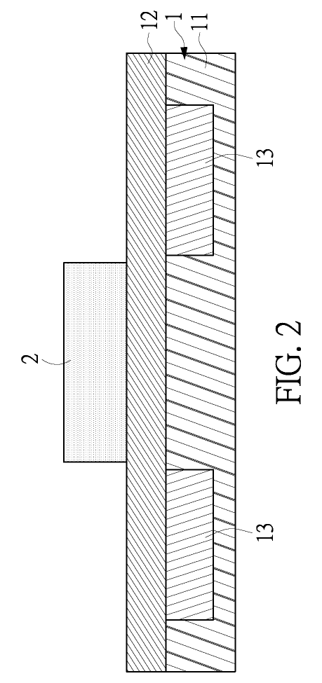

Step S102 includes forming a light-shielding pattern 2 between the two sensing regions 13. As shown in FIG. 2, the light-shielding pattern 2 protrudes from the film layer 12, and the light-shielding pattern 2 is staggered with the two sensing regions 13 along a longitudinal direction for reducing noise between any neighboring two optical paths. Further, the light-shielding pattern 2 is disposed above a spacing area between the two sensing regions 13, and the light-shielding pattern 2 preferably does not block the optical paths received by the two sensing regions 13. The light-shielding pattern 2 can be made of a black matrix resist (BM).

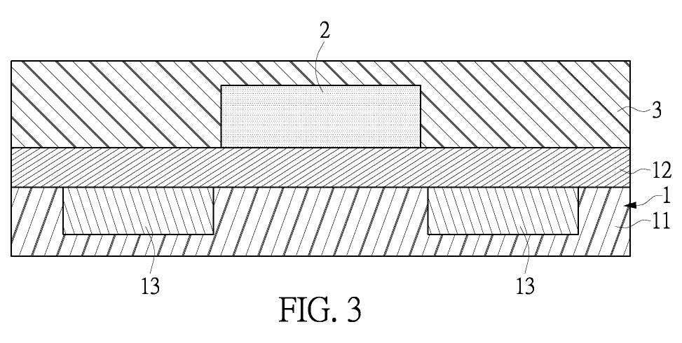

Step S103 includes forming an inorganic layer 3 on the substrate 1. As shown in FIG. 3, the inorganic layer 3 covers the film layer 12 and the light-shielding pattern 2. The inorganic layer 3 can be made of silicon dioxide (SiO₂) and serves as an etching target layer for a subsequent pattern transfer process, but the present disclosure is not limited thereto.

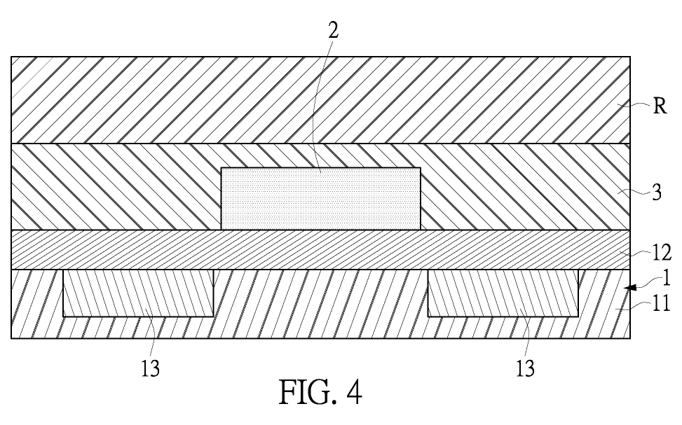

Step S104 includes forming a photoresist layer R on the inorganic layer 3, for example, by a spin-coating process. As shown in FIG. 4, the photoresist layer R can be made of polymethyl methacrylate (PMMA), but the present disclosure is not limited thereto.

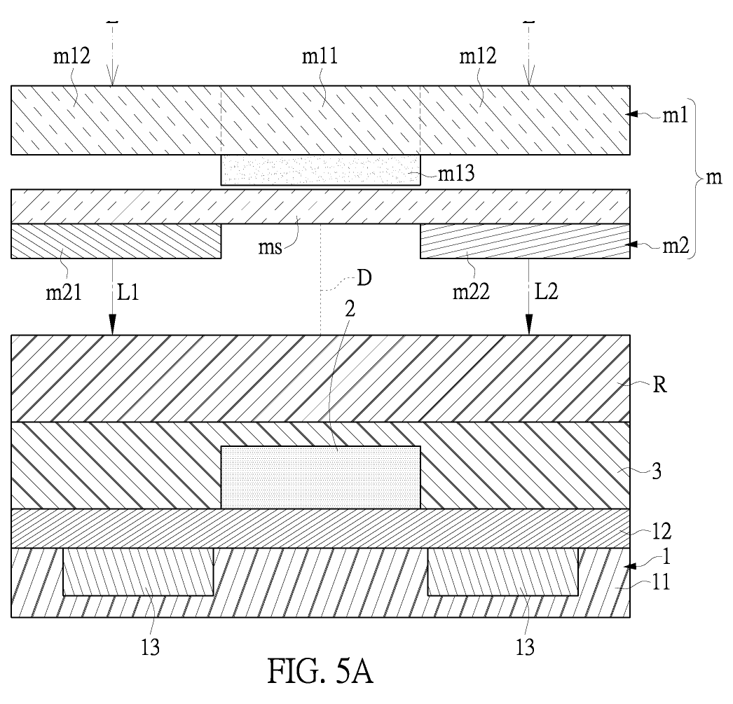

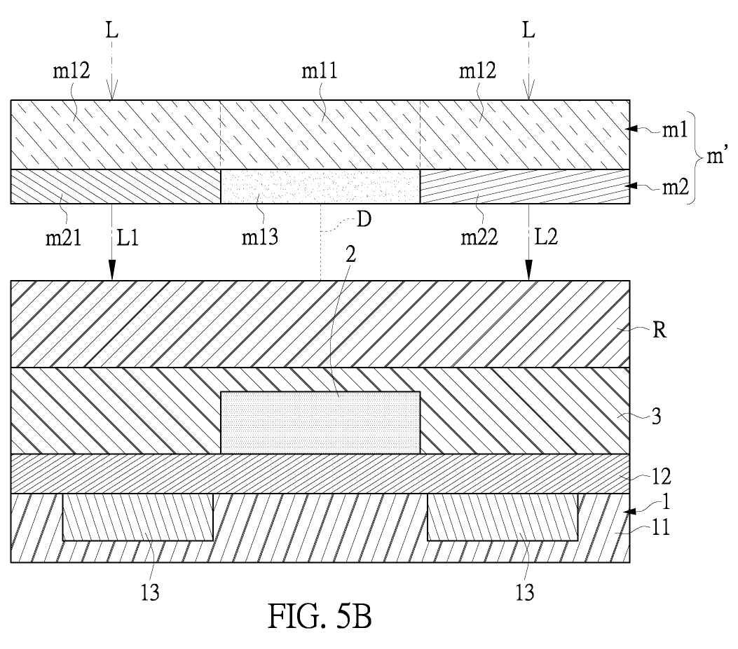

Step S105: arranging a grayscale mask m above the photoresist layer R along an exposure path D to perform a single exposure process on the photoresist layer R. As shown in FIG. 5A, the grayscale mask m includes a first mask m1 and a second mask m2. The second mask m2 is optically stacked with the first mask m1. The first mask m1 has a light-shielding region m11 and two light-transmitting regions m12 located on two sides of the light-shielding region m11. During the exposure process, the light-shielding region m11 of the first mask m1 corresponds to the light-shielding pattern 2 on the substrate 1 along the exposure path D (i.e., the longitudinal direction), and the two light-transmitting regions m12 respectively correspond to the two sensing regions 13. It should be noted that the longitudinal direction refers to the direction along the exposure path D, which is the direction perpendicular to the surface of the substrate 1. As shown in FIG. 5A, the first mask m1 is formed by disposing a light-shielding structure m13, such as a metal thin film (e.g., nickel) or BM, on a lower surface of an optical substrate so as to define the light-shielding region m11 and the two light-transmitting regions m12, but the present disclosure is not limited thereto.

The second mask m2 has a first light filtering region m21 and a second light filtering region m22 that are spaced apart from each other. Positions of the first light filtering region m21 and the second light filtering region m22 respectively correspond and overlap with the two light-transmitting regions m12 of the first mask m1 along the exposure path D, and respectively correspond to the two sensing regions 13 of the substrate 1.

Furthermore, the first light filtering region m21 has a first light transmittance, and the second light filtering region m22 has a second light transmittance. The first light transmittance is different from the second light transmittance. Accordingly, during a single exposure process, different exposure energy distributions can be generated and exposed on the photoresist layer R corresponding to the first light filtering region m21 and the second light filtering region m22. In addition, both the first light transmittance and the second light transmittance are significantly lower than the light transmittance of the two light-transmitting regions m12 of the first mask m1.

In some embodiments, the first light filtering region m21 and the second light filtering region m22 can be made of thin films having partial light-transmitting characteristics. The materials of the thin films can be metallic or alloy films such as chromium, nickel-chromium alloy, molybdenum, or titanium. Alternatively, the thin films can be dielectric multilayer films, such as a stack of silicon dioxide and titanium dioxide or a stack of silicon dioxide and silicon nitride.

In the present embodiment, the second mask m2 is disposed below the first mask m1 along the exposure path D and is positioned closer to the photoresist layer R than the first mask m1, but the present disclosure is not limited thereto. In an unillustrated embodiment, the second mask m2 can be disposed above the first mask m1 and positioned farther away from the photoresist layer R than the first mask m1.

In the present embodiment, the second mask m2 further includes a light-transmitting substrate ms, and the light-transmitting substrate ms is disposed below the first mask m1. Further, the first light filtering region m21 and the second light filtering region m22 are respectively formed on the bottom surface of the light-transmitting substrate ms, and are optically stacked with the first mask m1 through the light-transmitting substrate ms, so as to be spaced apart from the first mask m1.

The light-transmitting substrate ms and the aforementioned optical substrate each can be a silica glass substrate, a fused quartz substrate, or a sapphire substrate, but the present disclosure is not limited thereto.

Step S105 further includes performing the exposure process by directing an exposure light L passing through the grayscale mask m to expose the photoresist layer R. During the exposure process, the exposure light L passes through the first light filtering region m21 and the second light filtering region m22 so that different areas of the photoresist layer R receive different exposure energies in a single exposure process.

Specifically, during the exposure process, the grayscale mask m receives the exposure light L. The exposure light L passes through the two light-transmitting regions m12 of the first mask m1, and then passes through the first light filtering region m21 and the second light filtering region m22 of the second mask m2 to respectively form a first exposure light L1 and a second exposure light L2 having different exposure energies. Consequently, different areas of the photoresist layer R are exposed with the different exposure energies within the single exposure process. It should be noted that the “single exposure” refers to a process in which the photoresist layer R is exposed only once through the different exposure energies produced due to the different light transmittances of the grayscale mask m, but the present disclosure is not limited thereto.

Referring to FIG. 5B, a schematic view of another embodiment of the grayscale mask m’ used in the exposure process of the present disclosure is shown. In the present embodiment, the second mask m2 of the grayscale mask m’ does not include a light-transmitting substrate. The first light filtering region m21 and the second light filtering region m22 are respectively and directly disposed on and overlapped with the two light-transmitting regions m12 of the first mask m1. Further, the first light filtering region m21 and the second light filtering region m22 are located on both sides of the light-shielding region m11 and the light-shielding structure m13, thereby forming the second mask m2. Accordingly, after receiving the exposure light L, the grayscale mask m’ can generate a first exposure light L1 and a second exposure light L2 having different exposure energies. In the present embodiment, the heights of the first light filtering region m21 and the second light filtering region m22 are flush with the height of the light-shielding structure m13, but the present disclosure is not limited thereto. The height of the light-shielding structure m13 can also be slightly higher than the heights of the first light filtering region m21 and the second light filtering region m22.

It should be noted that the two grayscale masks m and m’ described above are used in the method for manufacturing the semiconductor device E of the present embodiment. However, the present disclosure is not limited thereto. The grayscale masks m and m’ can also be commercial products that can be independently applied to exposure processes of other semiconductor fabrication procedures.

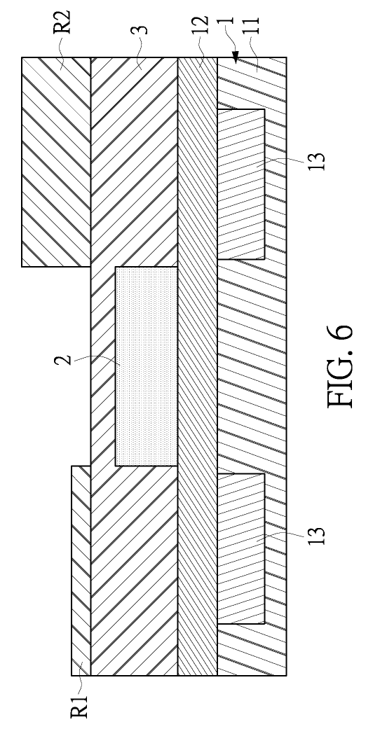

Step S106 includes performing a development process on the photoresist layer R. As shown in FIG. 6, the development process forms a first remaining photoresist R1 and a second remaining photoresist R2 that are spaced apart from each other. The first remaining photoresist R1 and the second remaining photoresist R2 have different heights, thereby forming a photoresist pattern with a height difference. For example, the height of the second remaining photoresist R2 is greater than that of the first remaining photoresist R1.

Furthermore, the first remaining photoresist R1 and the second remaining photoresist R2 respectively correspond to the two sensing regions 13 of the substrate 1 along the longitudinal direction. The unexposed portions of the photoresist layer R are removed during the development process, so that the surface of the inorganic layer 3 corresponding to the region of the light-shielding pattern 2 is exposed.

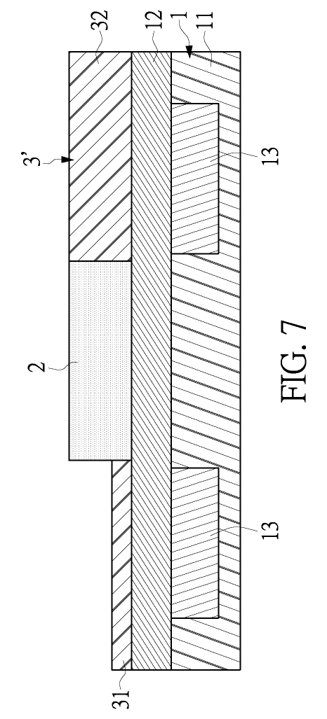

Step S107 includes performing a pattern transfer process. As shown in FIG. 7, the photoresist pattern with the height difference is transferred onto the inorganic layer 3 by an ion etching process, so that the inorganic layer 3 is formed into an etched microstructure 3’.

More specifically, the pattern transfer process is performed after the development process. The pattern transfer process includes etching the first remaining photoresist R1 and the second remaining photoresist R2 to transfer the photoresist pattern onto the inorganic layer 3. As a result, a first etched microstructure 31 and a second etched microstructure 32 are respectively formed at positions corresponding to the first remaining photoresist R1 and the second remaining photoresist R2.

The ion etching process can be carried out using an inductively coupled plasma reactive ion etching (ICP-RIE) system. Carbon tetrafluoride (CF₄) or other fluorine-containing gases can be used as the etching gas source. The carbon tetrafluoride plasma can react with the inorganic layer 3 (e.g., SiO₂ layer), to produce volatile by-products such as SiF₄. Under appropriate plasma conditions, the process achieves either anisotropic or isotropic etching of the inorganic material.

Furthermore, since the first remaining photoresist R1 and the second remaining photoresist R2 have different heights, the ion etching proceeds at different rates. In a region where the remaining photoresist is thinner, such as the first remaining photoresist R1, the plasma etches through the inorganic layer 3 more quickly, so as to form a first etched microstructure 31 with a deeper etching depth, that is, a thinner remaining thickness. Conversely, in a region where the remaining photoresist is thicker, such as the second remaining photoresist R2, the etching resistance is greater, and the corresponding region of the inorganic layer 3 is etched more slowly, so as to form a second etched microstructure 32 that is thicker than the first etched microstructure 31.

The portion of the inorganic layer 3 corresponding the region not protected by the remaining photoresist is fully exposed and rapidly etched, thereby exposing the light-shielding pattern 2. The first etched microstructure 31 and the second etched microstructure 32 are located on both sides of the light-shielding pattern 2 and are spaced apart from each other. In the longitudinal direction, the first etched microstructure 31 and the second etched microstructure 32 respectively correspond to the two sensing regions 13 of the substrate 1.

It should be noted that, under the selected etching conditions, the ion etching process has a relatively high etching rate on the inorganic layer 3 and a sufficiently high selectivity relative to the film layer 12 and the light-shielding pattern 2. Therefore, the film layer 12 and the light-shielding pattern 2 are not significantly etched.

In an unillustrated embodiment of the present disclosure, after completing the pattern transfer process (Step S107), a residual photoresist removal process can also be performed to remove residual photoresist material that remains in both patterned and non-patterned areas after the ion etching process.

The residual photoresist removal process can, for example, be carried out by an oxygen plasma reactive ion etching (RIE, O₂ plasma) to perform cleaning treatment, but the present disclosure is not limited thereto.

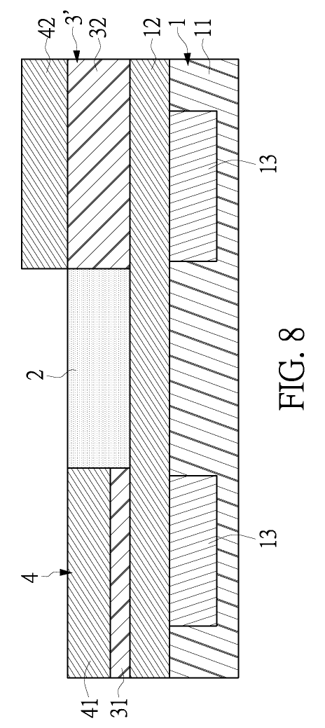

Step S108 includes forming a stacked film layer 4 on the etched microstructure 3’. As shown in FIG. 8, the stacked film layer 4 includes a first stacked film layer 41 formed on the first etched microstructure 31 and a second stacked film layer 42 formed on the second etched microstructure 32. The first stacked film layer 41 and the second stacked film layer 42 have substantially the same thickness. Therefore, the surface height difference between the first stacked film layer 41 and the second stacked film layer 42 corresponds to the height difference between the first etched microstructure 31 and the second etched microstructure 32. The surface heights of the first stacked film layer 41 and the second stacked film layer 42 are respectively higher than or equal to the height of the light-shielding pattern 2. In addition, the stacked film layer 4 is not formed on the light-shielding pattern 2, but the present disclosure is not limited thereto. The stacked film layer 4 can be a reflective layer, for example, formed by stacking multiple layers of silver (Ag) or configured as distributed Bragg reflectors (DBRs) so as to provide desired optical filtering or reflective characteristics, but the present disclosure is not limited thereto.

In some embodiments, before forming the stacked film layer 4 in Step S108, a photolithography process can first be performed to form corresponding openings above the first etched microstructure 31 and the second etched microstructure 32, while the region of the light-shielding pattern 2 remains covered. The stacked film layer 4 is then deposited within the corresponding openings, and after the deposition is completed, the photoresist is removed. In this way, the stacked film layer 4 can be selectively formed only on the first etched microstructure 31 and the second etched microstructure 32 without covering the light-shielding pattern 2. However, the present disclosure is not limited to the above-mentioned approach, and other selective deposition or removal techniques can also be used to achieve the same result.

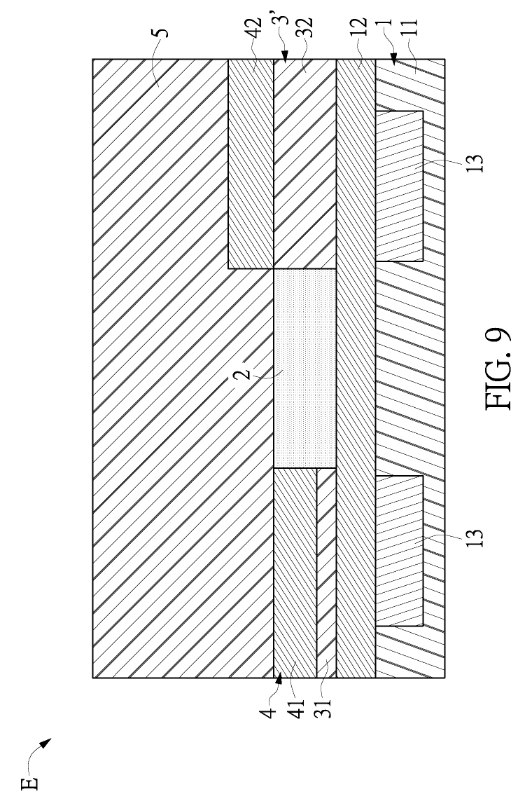

Step S109 includes forming a capping layer 5 on the stacked film layer 4 and the light-shielding pattern 2. As shown in FIG. 9, the outer surface of the capping layer 5 is a planar surface. The capping layer 5 can be made of silicon dioxide, but the present disclosure is not limited thereto.

### [Semiconductor Device]

Referring to FIG. 9, the embodiment of the present disclosure provides a semiconductor device E. The semiconductor device includes a substrate 1 and an etched microstructure 3’. The etched microstructure 3’ includes a first etched microstructure 31 and a second etched microstructure 32 that are respectively formed on the substrate 1. The first etched microstructure 31 and the second etched microstructure 32 are spaced apart from each other and have different heights.

In addition, the patterns of the first etched microstructure 31 and the second etched microstructure 32 respectively correspond to the first light filtering region m21 and the second light filtering region m22 of the grayscale mask m described in the above embodiments.

Furthermore, the light-shielding pattern 2 is disposed between the first etched microstructure 31 and the second etched microstructure 32. The height of the first etched microstructure 31 is different from that of the second etched microstructure 32, and both heights are less than or equal to the height of the light-shielding pattern 2. For example, the height of the first etched microstructure 31 is smaller than that of the light-shielding pattern 2, while the height of the second etched microstructure 32 is equal to that of the light-shielding pattern 2. The substrate 1 further includes at least two sensing regions 13 spaced apart from each other, and the light-shielding pattern 2 is located above a spacing area between the two sensing regions 13. The light-shielding pattern 2 does not block the optical paths received by the two sensing regions 13.

The semiconductor device E further includes a stacked film layer 4 disposed on the etched microstructure 3’. The surface height difference of the stacked film layer 4 corresponds to the height difference of the etched microstructure 3’. Furthermore, the substrate 1 further includes a film layer 12 covering the two sensing regions 13, and the film layer 12 corresponds to the stacked film layer 4.

The semiconductor device E further includes a capping layer 5 formed on the substrate 1 to encapsulate the light-shielding pattern 2, the etched microstructure 3’, and the stacked film layer 4. The outer surface of the capping layer 5 is designed to be a planar surface. Moreover, the semiconductor device E can serve as a multi-spectral optical filter that includes at least two Fabry–Pérot (F–P) cavity structures. One F–P cavity structure (i.e., a first F–P cavity structure) is composed of the film layer 12, the first etched microstructure 31, and the first stacked film layer 41, and another F–P cavity structure (i.e., a second F–P cavity structure) is composed of the film layer 12, the second etched microstructure 32, and the second stacked film layer 42. Due to the thickness difference between the first etched microstructure 31 and the second etched microstructure 32, the two F–P cavity structures correspond to different optical channels that filter light of different wavelength bands. In addition, the light-shielding pattern 2, which is disposed between the neighboring two F–P cavity structures, effectively reduces optical crosstalk between the channels. The capping layer 5 covers the entire structure, providing the multi-spectral optical filter with enhanced structural stability and reliability.

### [Beneficial Effects of the Embodiments]

In summary, the method for manufacturing the semiconductor device according to the embodiment of the present disclosure utilizes a grayscale mask having regions with different light transmittances. Through a single exposure process, microstructures with height differences can be formed on the photoresist layer. By subsequently performing pattern transfer and etching processes, corresponding etched microstructures with height differences can be obtained. Compared with conventional photolithography techniques that employ electron beam (EB) direct writing or multiple-mask exposures, the method of the present disclosure significantly shortens the process steps, reduces manufacturing cost and processing time, and minimizes structural precision loss caused by multiple alignment errors. As a result, manufacturing efficiency and yield are substantially improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a semiconductor device, comprising:
providing a substrate;
forming an inorganic layer on the substrate;
forming a photoresist layer on the inorganic layer;
performing a photolithography process on the photoresist layer through a grayscale mask to form a photoresist pattern having a height difference; and
performing a pattern transfer process to transfer the photoresist pattern to the inorganic layer by ion etching such that the inorganic layer is formed into an etched microstructure having a height difference;
wherein the grayscale mask includes:
a first mask having a light-shielding region and two light-transmitting regions located at two sides of the light-shielding region; and
a second mask optically stacked with the first mask; wherein the second mask has a first light filtering region and a second light filtering region respectively aligned with the two light-transmitting regions along an exposure path; wherein the first light filtering region and the second light filtering region have different light transmittances.

2. The method according to claim 1, wherein the photolithography process includes
performing an exposure process on the photoresist layer by directing an exposure light through the grayscale mask so that the exposure light passes through the first light filtering region and the second light filtering region to expose different areas of the photoresist layer with different exposure energies; and
performing a development process on the photoresist layer to form the photoresist pattern having the height difference.

3. The method according to claim 2, wherein, during the exposure process, the second mask is disposed below the first mask and closer to the photoresist layer than the first mask.

4. The method according to claim 1, wherein, after the pattern transfer process, the manufacturing method further comprises:
forming a stacked film layer on the etched microstructure, wherein the stacked film layer has a surface height difference corresponding to the height difference of the etched microstructure.

5. The method according to claim 4, wherein, after forming the stacked film layer, the manufacturing method further comprises:
forming a capping layer on the stacked film layer, wherein an outer surface of the capping layer is a planar surface.

6. The method according to claim 1, wherein the substrate includes a base and a film layer formed on the base; wherein the base further includes at least two sensing regions spaced apart from each other, and the film layer covers the two sensing regions.

7. The method according to claim 6, wherein, before forming the inorganic layer on the substrate, the manufacturing method further comprises:
forming a light-shielding pattern on the film layer, and after forming the inorganic layer, the inorganic layer covers the film layer and the light-shielding pattern;
wherein the light-shielding pattern is disposed above a spacing area between the two sensing regions and does not block light paths received by the two sensing regions.

8. The method according to claim 7, wherein, during the exposure process, the light-shielding region of the first mask corresponds to the light-shielding pattern on the film layer along the exposure path, and the first light filtering region and the second light filtering region of the second mask respectively correspond to the two sensing regions of the substrate.

9. A grayscale mask suitable for an exposure process of a semiconductor device, the grayscale mask comprising:
a first mask having a light-shielding region and two light-transmitting regions located at two sides of the light-shielding region; and
a second mask optically stacked with the first mask; wherein the second mask has a first light filtering region and a second light filtering region respectively aligned with the two light-transmitting regions;
wherein the first light filtering region and the second light filtering region have different light transmittances.

10. The grayscale mask according to claim 9, wherein the second mask further includes a light-transmitting substrate, and the first light filtering region and the second light filtering region are disposed on the light-transmitting substrate to be stacked with the first mask.

11. The grayscale mask according to claim 9, wherein the first light filtering region and the second light filtering region of the second mask are directly disposed on the two light-transmitting regions of the first mask.

12. A semiconductor device comprising:
a substrate; and
an etched microstructure formed on the substrate, the etched microstructure including a first etched microstructure and a second etched microstructure that are spaced apart from each other and have different heights;
wherein patterns of the first etched microstructure and the second etched microstructure respectively correspond to the first light filtering region and the second light filtering region of the grayscale mask according to claim 9.

13. A semiconductor device comprising:
a substrate;
an etched microstructure including a first etched microstructure and a second etched microstructure that are respectively disposed on the substrate and spaced apart from each other; and
a light-shielding pattern disposed between the first etched microstructure and the second etched microstructure;
wherein a height of the first etched microstructure is different from a height of the second etched microstructure and is less than or equal to a height of the light-shielding pattern.

14. The semiconductor device according to claim 13, wherein the substrate further includes at least two sensing regions spaced apart from each other and a film layer that covers the two sensing regions, the light-shielding pattern is disposed above a spacing area between the two sensing regions and does not block light paths received by the two sensing regions.

15. The semiconductor device according to claim 14, further comprising
a first stacked film layer and a second stacked film layer that are respectively formed on the first etched microstructure and the second etched microstructure,
wherein the light-shielding pattern is disposed between the first stacked film layer and the second stacked film layer.

16. The semiconductor device according to claim 13, further comprising
a capping layer formed on the substrate to encapsulate the etched microstructure, wherein an outer surface of the capping layer is a planar surface.

17. The semiconductor device according to claim 15, wherein the surface heights of the first stacked film layer and the second stacked film layer are respectively higher than or equal to the height of the light-shielding pattern.

18. The semiconductor device according to claim 15, wherein the film layer, the first etched microstructure, and the first stacked film layer together define a first Fabry–Pérot cavity structure, and wherein the film layer, the second etched microstructure, and the second stacked film layer together define a second Fabry–Pérot cavity structure.

19. The semiconductor device according to claim 18, wherein a thickness difference between the first etched microstructure and the second etched microstructure causes the first and second Fabry–Pérot cavity structures to correspond to different optical channels for filtering light of different wavelength bands.
